(19) United States
(12) Patent Application Publication
(10) Pub. No.: US 2016/0208382 A1
(43) Pub. Date: Jul. 21, 2016

(54) SEMICONDUCTOR MANUFACTURING APPARATUS

(71) Applicant: Kabushiki Kaisha Toshiba, Minato-ku (JP)

(72) Inventors: Kensei Takahashi, Kuwana (JP); Kazuhiro Matsuo, Yokkaichi (JP); Fumiki Aiso, Kuwana (JP)

(73) Assignee: Kabushiki Kaisha Toshiba, Minato-ku (JP)

(21) Appl. No.: 14/812,068

(22) Filed: Jul. 29, 2015

(30) Foreign Application Priority Data
Jan. 21, 2015 (JP) 2015-009661

(51) Int. Cl. C23C 16/455; C23C 16/44

(52) U.S. Cl. CPC C23C 16/45544; C23C 16/4412

(57) ABSTRACT

A semiconductor manufacturing apparatus according to an embodiment includes a reaction chamber that is capable of housing a semiconductor substrate and is capable of forming a deposited film on a surface of the semiconductor substrate. A first container stores a source of the deposited film. A second container stores a source gas generated in the first container, and supplies the source gas to the reaction chamber. A first pipe connects the first container and the second container. A second pipe supplies an inert gas to the second container.

### CROSS REFERENCE TO RELATED APPLICATIONS

This application is based upon and claims the benefit of priority from the prior Japanese Patent Application No. 2015-009661, filed on Jan. 21, 2015, the entire contents of which are incorporated herein by reference.

### FIELD

The embodiments of the present invention relate to a semiconductor manufacturing apparatus.

### BACKGROUND

By an ALD (Atomic Layer Deposition) method, a source gas (a precursor) is supplied to a reaction chamber and a source film is formed on surfaces of semiconductor wafers in the reaction chamber using the source gas. Subsequently, the source film is oxidized, thereby forming a deposited film (an oxide film) at an atomic layer level on the semiconductor wafers. By repeating such a forming cycle (hereinafter, also simply “cycle”) of a deposited film at an atomic layer level, a deposited film of a desired thickness is formed on the semiconductor wafers.

Conventionally, by the ALD method, a source of a deposited film is sublimated to generate the source gas. The source gas is carried to the reaction chamber using an inert gas (a carrier). In order to cause the source film to uniformly adhere onto the semiconductor wafers, a fixed amount of the source gas needs to be supplied to the reaction chamber. However, when the cycle described above is repeated, the source gas in a source tank gradually decreases. In order to address this problem, the supply amount of the source gas is conventionally increased by increasing a flow rate of the inert gas (carrier gas) to be supplied into the source tank.

However, if the flow rate of the carrier gas is simply increased, a ratio (a partial pressure) of the amount of the source gas to the total gas flow rate is lowered while the amount of the source gas is increased. Accordingly, there is a case where an increase in the flow rate of the carrier gas results in an insufficient supply amount of the source gas.

Furthermore, the reaction chamber is in a vacuum state while a container in which the source gas is to be generated is at a vapor pressure of the source gas. Therefore, when the source gas is supplied in a first cycle of the ALD method, the source gas or a reaction product rushes into a pipe between the reaction chamber and the container due to a pressure difference between the reaction chamber and the container. At this time, the source (a powder source, for example) or the reaction product in the container may enter the pipe and become a cause of particles.

### BRIEF DESCRIPTION OF THE DRAWINGS

FIG. 1 shows an example of a configuration of a film forming apparatus 1 according to a first embodiment;

FIGS. 2 to 10 are explanatory diagrams showing an example of the operation of the film forming apparatus 1 according to the first embodiment;

FIG. 11 is a flowchart showing an example of the operation of the film forming apparatus 1 according to the first embodiment; and

FIG. 12 shows a configuration of a film forming apparatus 2 according to a second embodiment.

### DETAILED DESCRIPTION

Embodiments will now be explained with reference to the accompanying drawings. The present invention is not limited to the embodiments.

A semiconductor manufacturing apparatus according to an embodiment includes a reaction chamber that is capable of housing a semiconductor substrate and is capable of forming a deposited film on a surface of the semiconductor substrate. A first container stores a source of the deposited film. A second container stores a source gas generated in the first container, and supplies the source gas to the reaction chamber. A first pipe connects the first container and the second container. A second pipe supplies an inert gas to the second container.

### First Embodiment

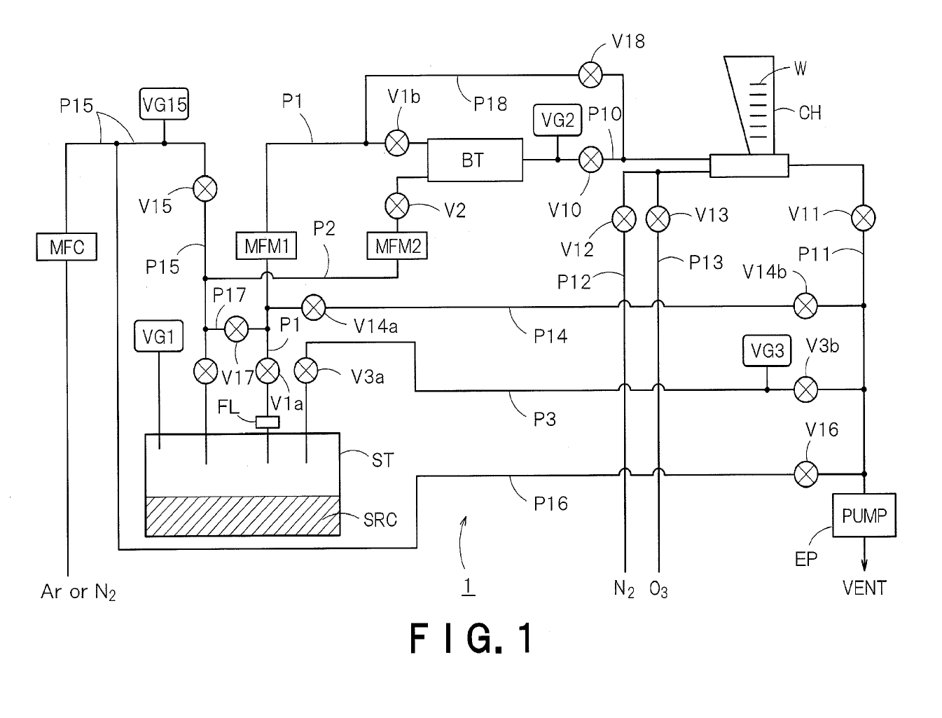

FIG. 1 shows an example of a configuration of a film forming apparatus 1 according to a first embodiment. The film forming apparatus 1 is, for example, an ALD film forming apparatus that repeatedly deposits a material film at an atomic layer level, thereby forming a deposited film of a desired thickness on semiconductor wafers.

The film forming apparatus 1 includes a reaction chamber CH, a source tank ST, a buffer tank BT, a discharging pump EP, pipes P1 to P3 and P10 to P18, valves V1a to V3b and V10 to V18, flowmeters MFM1 and MFM2, pressure gauges VG (VG1, VG2, VG3, and VG15), and a flow rate controller MFC.

The reaction chamber CH can house therein semiconductor substrates W and is used to form a deposited film on surfaces of the semiconductor substrates W by the ALD method. A source gas (a precursor) is supplied to the reaction chamber CH and a source film is formed on the surfaces of the semiconductor substrates W. By oxidizing the source film, a deposited film (an oxide film) at an atomic layer level is formed on the semiconductor substrates W. By repeating a forming cycle of the deposited film at the atomic layer level, a deposited film of a desired thickness is formed on semiconductor wafers.

The source tank ST serving as a first container stores therein a source of a deposited film that is to be deposited on the surfaces of the semiconductor substrates W. For example, the source tank ST stores therein a solid powdery source. The source is, for example, AlCl₃, HfCl₄, or ZrCl₃. The source tank ST is temperature-adjusted by a heater (not shown) and generates the source gas by sublimating the source. The heater is controlled by a controller (not shown).

When AlCl₃ is used as the source, an AlCl₃ gas is generated as the source gas. In this case, AlCl₃ adheres on the surfaces of the semiconductor substrates W and Al₂O₃ (alumina) being an oxide film of AlCl₃ is formed thereon. When HfCl₄ is used as the source, an HfCl₄ gas is generated as the source gas. In this case, HfCl₄ adheres on the surfaces of the semiconductor substrates W and HfO₂ (hafnia) being an oxide film of HfCl₄ is formed thereon. When ZrCl₃ is used as the source, a ZrCl₃ gas is generated as the source gas. In this case, ZrCl₃ adheres on the surfaces of the semiconductor substrates W and Zr₂O₃ (zirconia) being an oxide film of ZrCl₃ is formed thereon.

The buffer tank BT serving as a second container accumulates therein a certain amount of the source gas generated in the source tank ST and supplies the source gas to the reaction chamber CH. The capacity of the buffer tank BT is set to supply a certain amount of the source gas to the reaction chamber CH. For example, the capacity of the buffer tank BT enables accumulation of a certain amount of the source gas required to form an oxide film at an atomic layer level on the semiconductor substrates W in the reaction chamber CH. However, in order to determine the amount of the source gas to be supplied to the reaction chamber CH according to the capacity of the buffer tank BT, the capacity of the buffer tank BT needs to be smaller than that of the source tank ST. An inert gas can be introduced into the buffer tank BT to pressurize the inside of the buffer tank BT after the certain amount of the source gas once enters the buffer tank BT. This is because the amount of the source gas accumulated in the buffer tank BT is not changed in this case while the pressure in the buffer tank BT is increased. The buffer tank BT is made of a metal or the like having a resistance to high pressures or high temperatures.

The discharging pump EP serving as a discharging device is provided to discharge gases in the reaction chamber CH, the source tank ST, the buffer tank BT, the pipes P1 to P18, and the like.

The pipe P1 serving as a first pipe is connected between the source tank ST and the buffer tank BT and is provided to send the source gas from the source tank ST to the buffer tank BT. The valves V1a and V1b serving as a first valve are provided on the pipe P1 and the valves V1a and V1b can open or close a supply route of the source gas.

The pipe P2 serving as a second pipe is connected between the pipe P15 and the buffer tank BT and is provided to send an inert gas from the pipe P15 to the buffer tank BT. The valve V2 serving as a second valve is provided on the pipe P2 and the valve V2 can open or close a supply route of the inert gas.

The pipe P3 serving as a third pipe is connected between the source tank ST and the discharging pump EP and is provided to discharge a gas from the source tank ST. The valves V3a and V3b serving as a third valve are provided on the pipe P3 and the valves V3a and V3b can open or close a gas discharging route of the pipe P3.

The pipe P10 connects the buffer tank BT and the reaction chamber CH, and is provided to send the source gas and/or the inert gas in the buffer tank BT to the reaction chamber CH. The valve V10 is provided on the pipe P10 and the valve V10 can open or close a supply route of the source gas and/or the inert gas.

The pipe P11 connects the reaction chamber CH and the discharging pump EP, and is provided to discharge a gas from the reaction chamber CH. The valve V11 is provided on the pipe P11 and the valve V11 can open or close a gas discharging route of the pipe P11.

The pipe P12 is connected to the reaction chamber CH and is provided to supply a purge gas (a nitrogen gas N₂, for example) to the reaction chamber CH. The valve V12 is provided on the pipe P12 and the valve V12 can open or close a supply route of the purge gas.

The pipe P13 is connected to the reaction chamber CH and is provided to supply an oxidation gas (an ozone gas O₃, for example) to the reaction chamber CH. The valve V13 is provided on the pipe P13 and the valve V13 can open or close a supply route of the oxidation gas.

The pipe P14 is connected between the pipe P1 and the pipe P11 and is provided to discharge a gas in the source tank ST or the buffer tank BT. The valves V14a and V14b are provided on the pipe P14 and the valves V14a and V14b can open or close a discharging route of the pipe P14.

The pipe P15 is connected to the pipes P2 and P17 and the source tank ST and is provided to supply an inert gas (Ar or N₂, for example) to the pipes P2 and P17 and the source tank ST. The valve V15 is provided on the pipe P15 and the valve V15 can open or close a supply route of the inert gas.

The pipe P16 is connected between the pipe P15 and the discharging pump EP and is provided to discharge the inert gas. The valve V16 is provided on the pipe P16 and the valve V16 can open or close a supply route of the inert gas.

The pipe P17 is connected between the pipe P15 and the pipe P1 and is provided to introduce the inert gas into the pipe P1. The valve V17 is provided on the pipe P17 and the valve V17 can open or close a supply route of the inert gas to the pipe P1.

The pipe P18 is connected between the pipe P1 and the pipe P10 and is provided to supply the inert gas to the reaction chamber CH without through the buffer BT. The valve V18 is provided on the pipe P18 and the valve V18 can open or close a supply route of the inert gas to the reaction chamber CH.

The pipes P1 to P18 are made of a metal or the like having a pressure resistance and a temperature resistance. The valves V1 to V18 can be automatic electromagnetic valves or the like. The valves V1 to V18 are controlled to open or close by a controller (not shown) based on gas flow rates of the relevant pipes or pressures thereof.

The flowmeter (a mass flow meter) MFM1 is provided in the pipe P1 and measures a flow rate (sccm) of the source gas flowing through the pipe P1. The flowmeter MFM2 is provided in the pipe P2 and measures a flow rate (sccm) of the inert gas flowing through the pipe P2. The flow rate controller (mass flow controller) MFC is provided in the pipe P15 and controls a flow rate of the inert gas flowing through the pipe P15.

The pressure gauge VG1 is provided in the source tank ST and measures a pressure in the source tank ST. The pressure gauge VG2 is provided in the pipe P10 or in the buffer tank BT and measures a pressure in the buffer tank BT. The pressure gauge VG3 is provided in the pipe P3 and measures a pressure in the pipe P3. The pressure gauge VG15 is provided in the pipe P15 and measures a pressure in the pipe P15.

An operation of the film forming apparatus 1 according to the first embodiment is explained next.

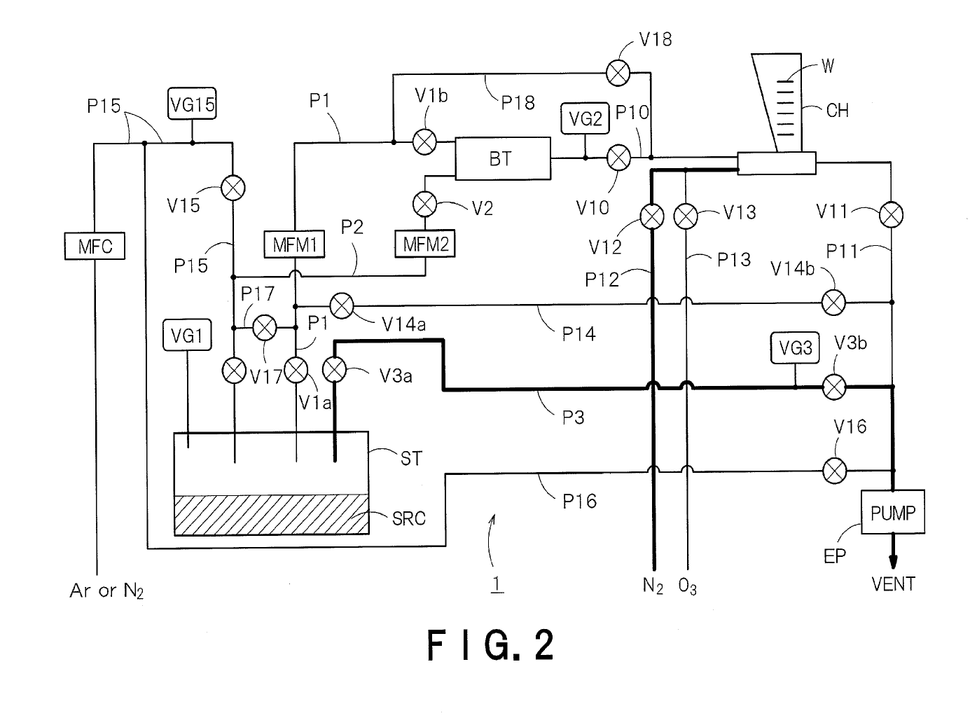

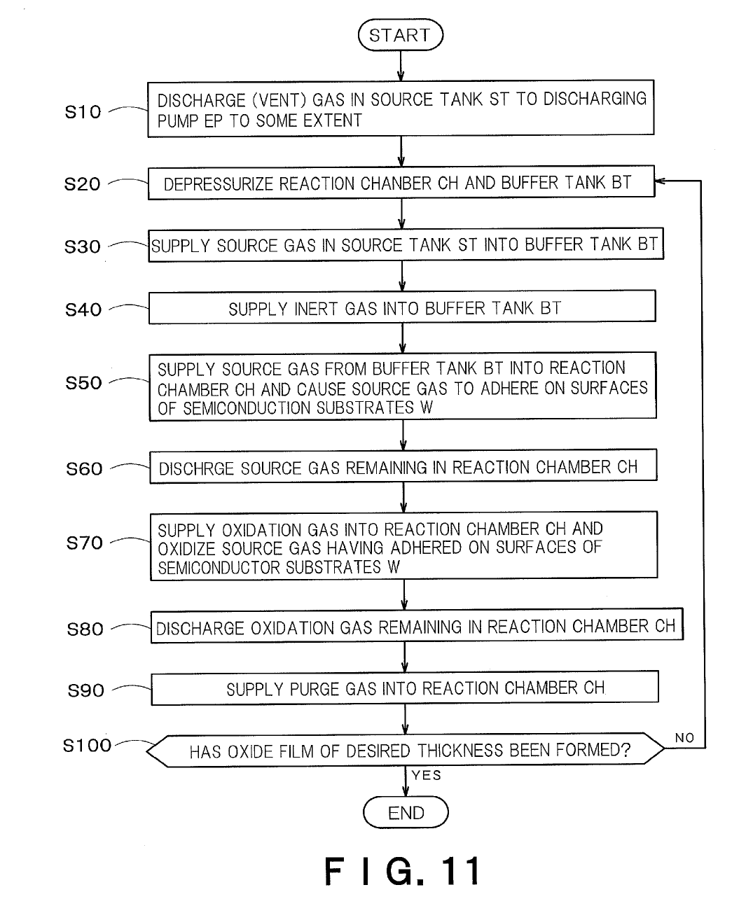

FIGS. 2 to 10 are explanatory diagrams showing an example of the operation of the film forming apparatus 1 according to the first embodiment. FIG. 11 is a flowchart showing an example of the operation of the film forming apparatus 1 according to the first embodiment. In FIGS. 2 to 10, thick lines indicate that gases are flowing through the corresponding pipes, respectively. It is assumed that the valves V1 to V18 are initially closed.

By the ALD method, a deposited film of a desired thickness is formed on the semiconductor substrates W by repeating the cycle of a deposited film at an atomic layer level as described above. In a first cycle of such a film forming process, the valves V3a and V3b as the third valve are first opened to open the gas discharging route of the third pipe P3 for a short time as shown in FIG. 2. Accordingly, a gas in the source tank ST is discharged (vented) to the discharging pump EP to some extent (Step S10).

At the start of a deposition process, the source tank ST heats a source SRC with the heater to be sublimated. For example, AlCl₃ sublimates to have a vapor pressure of about 1 Torr at about 100° C. AlCl₃ sublimates to have a vapor pressure of about 10 Torr at about 120° C. HfCl₄ sublimates to have a vapor pressure of about 1 Torr at about 170° C. Therefore, the source SRC sublimates in the source tank ST until it has a vapor pressure depending on a material of the source SRC and a temperature.

Meanwhile, if the buffer tank BT is depressurized to a pressure near a vacuum (equal to or lower than 1 Torr, for example) by the discharging pump EP and the source gas in the source tank ST is attempted to be supplied to the buffer tank BT from an initial time of the first cycle, a part of the source gas in the source tank ST rushes into the buffer tank BT due to a pressure difference between the buffer tank BT and the source tank ST. At this time, a solid source (a powder source, for example) in the source tank ST or a reaction product in the source tank ST gushes out to the buffer tank BT together with the source gas. In the first cycle of the film forming process, such a source or a reaction product is likely to be generated. If entering the reaction chamber CH through the buffer tank BT, the source or the reaction product may adhere on the semiconductor substrates W as particles.

Therefore, in the first embodiment, the valves V3a and V3b open the gas discharging route of the pipe P3 at the start of the first cycle, thereby discharging a part of the source gas in the source tank ST to the discharging pump EP. Because the pipe P3 or the discharging pump EP is located downstream of the reaction chamber CH and the buffer tank BT, the source and the reaction product are discharged to the pipe P3 or the discharging pump EP and do not flow back to the reaction chamber CH and the buffer tank BT. Accordingly, it is possible to suppress the source or the reaction product in the first cycle from entering the reaction chamber CH and the buffer tank BT as particles. Because it suffices at Step S10 that the source and the reaction product are discharged to the pipe P3 or the discharging pump EP, it suffices to open the valves V3a and V3b only for a short time. At this time, the valve V12 is open and the reaction chamber CH is purged with the N₂ gas as shown in FIG. 2.

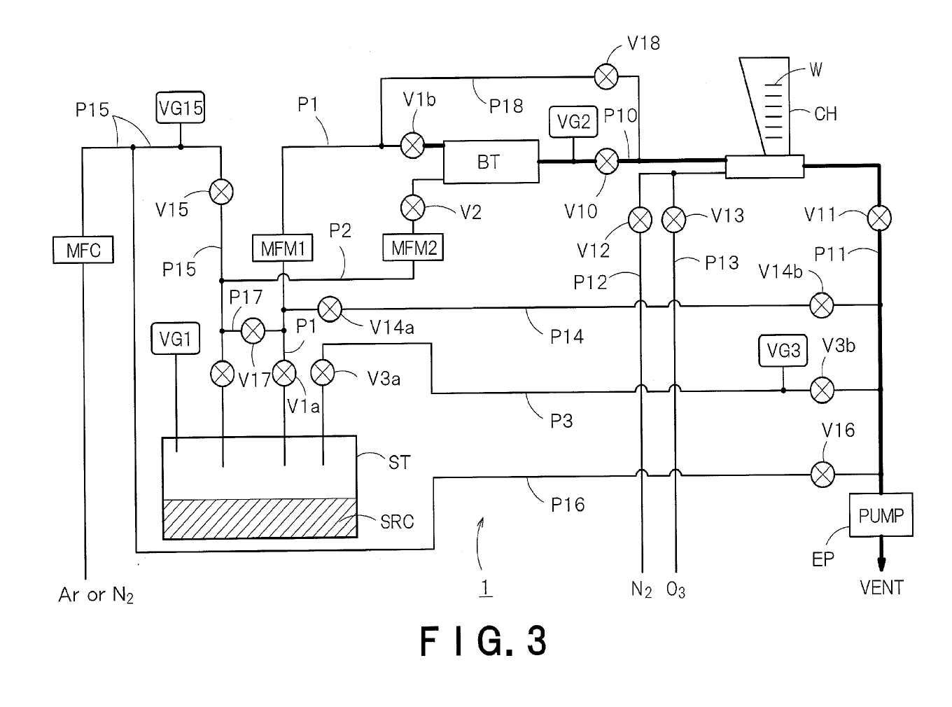

Next, after the valves V3a, V3b, and V12 are closed, the valves V10 and V11 open the gas discharging route, thereby discharging a gas in the buffer tank BT via the pipes P10 and P11 and the reaction chamber CH as shown in FIG. 3. Accordingly, the reaction chamber CH and the buffer tank BT are depressurized (Step S20). By depressurizing the buffer tank BT, the source gas can be introduced from the source tank ST to the buffer tank BT to accumulate the source gas in the buffer tank BT at Step S30 explained later.

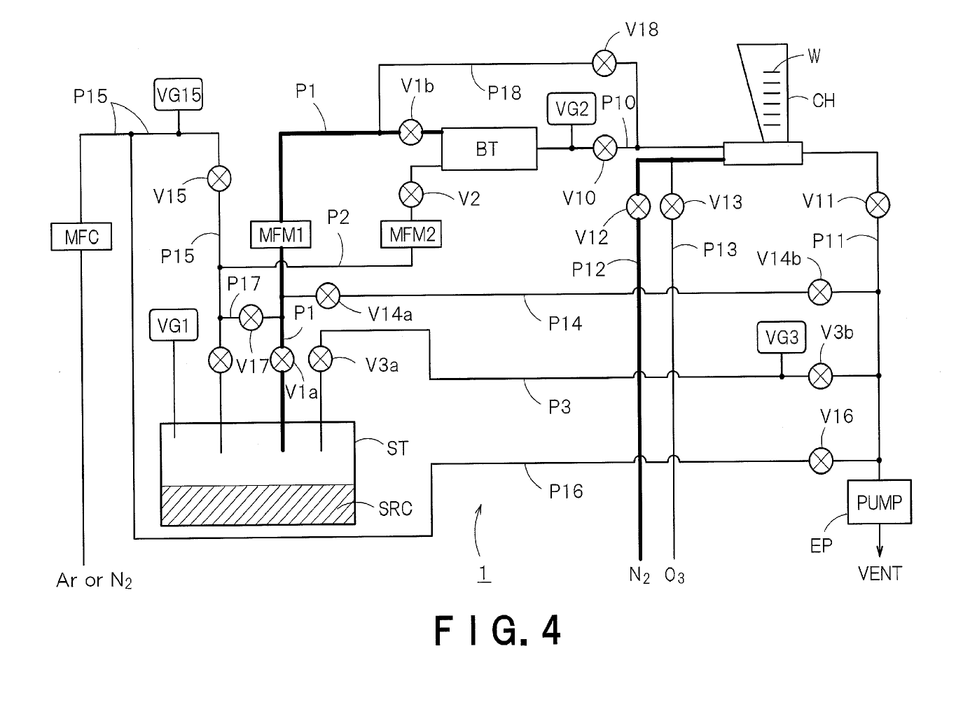

Subsequently, after the valves V10 and V11 are closed, the valves V1a and V1b open the supply route of the source gas, thereby supplying the source gas in the source tank ST into the buffer tank BT via the pipe P1 (Step S30) as shown in FIG. 4. The source gas at the vapor pressure is in the source tank ST and the inside of the buffer tank BT is depressurized. Therefore, the source gas in the source tank ST is introduced into the buffer tank BT. The buffer tank BT can store or accumulate therein the source gas in this way. The amount of the source gas to be stored or accumulated in the buffer tank BT can be preset based on the vapor pressure of the source gas, the pressure in the buffer tank BT, the capacity of the buffer tank BT, and the like. Therefore, the buffer tank BT can store or accumulate therein a preset certain amount of the source gas. At this time, the valve V2 closes the supply route of the inert gas to store or accumulate the certain amount of the source gas in the buffer tank BT and the inert gas is not supplied to the buffer tank BT.

At Step S10, apart of the source gas in the source tank ST is already discharged to the discharging pump EP and many of particles such as the source and the reaction product have been discharged to the pipe P3 or the discharging pump EP. Therefore, when the source gas in the source tank ST is supplied into the buffer tank BT at Step S30, few particles such as the source and the reaction product enter (disperse) to the buffer tank BT. At Step S30, the valve V12 is open and the reaction chamber CH is purged again with the N₂ gas as shown in FIG. 4.

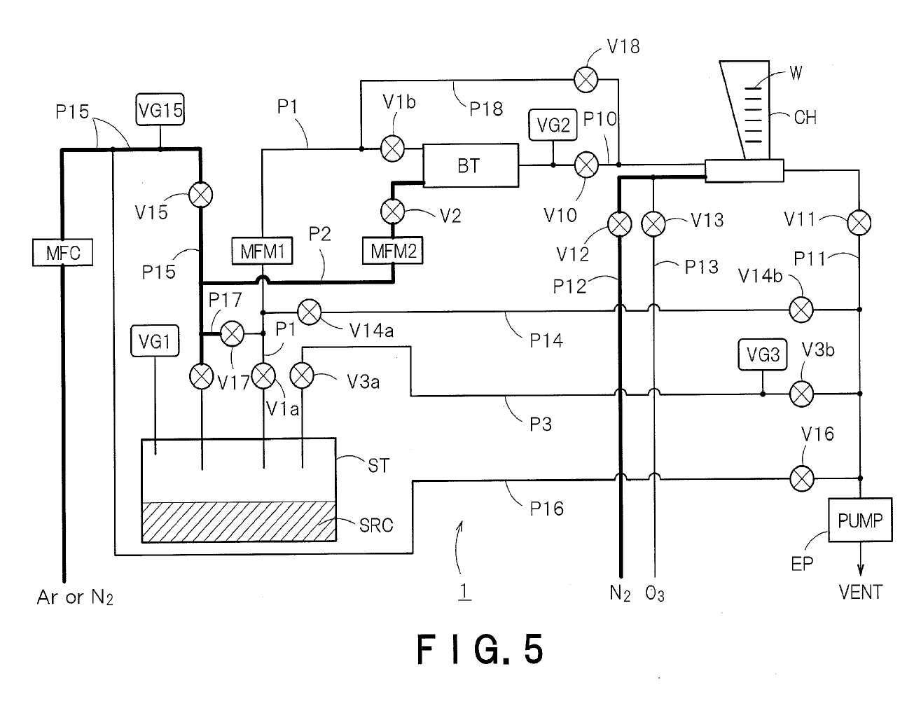

Next, after the valves V1a and V1b are closed, the valves V2 and V15 open the supply route of the inert gas and supply the inert gas into the buffer tank BT via the pipes P2 and P15 (Step S40) as shown in FIG. 5. Accordingly, the pressure in the buffer tank BT is increased to a certain level higher than that in the reaction chamber CH to enable the source gas in the buffer tank BT to be sufficiently introduced into the reaction chamber CH. At this time, while the inert gas is introduced into the buffer tank BT, the amount of the source gas in the buffer tank BT does not change. When the pressure in the buffer tank BT is sufficiently high only with the source gas, introduction of the inert gas into the buffer tank BT is unnecessary. A mixture gas of the source gas and the inert gas or the source gas in the buffer tank BT is hereinafter also collectively referred to simply as “source gas”. At Step S40, the valve V12 is open as shown in FIG. 5 and the reaction chamber CH is kept purged with the N₂ gas.

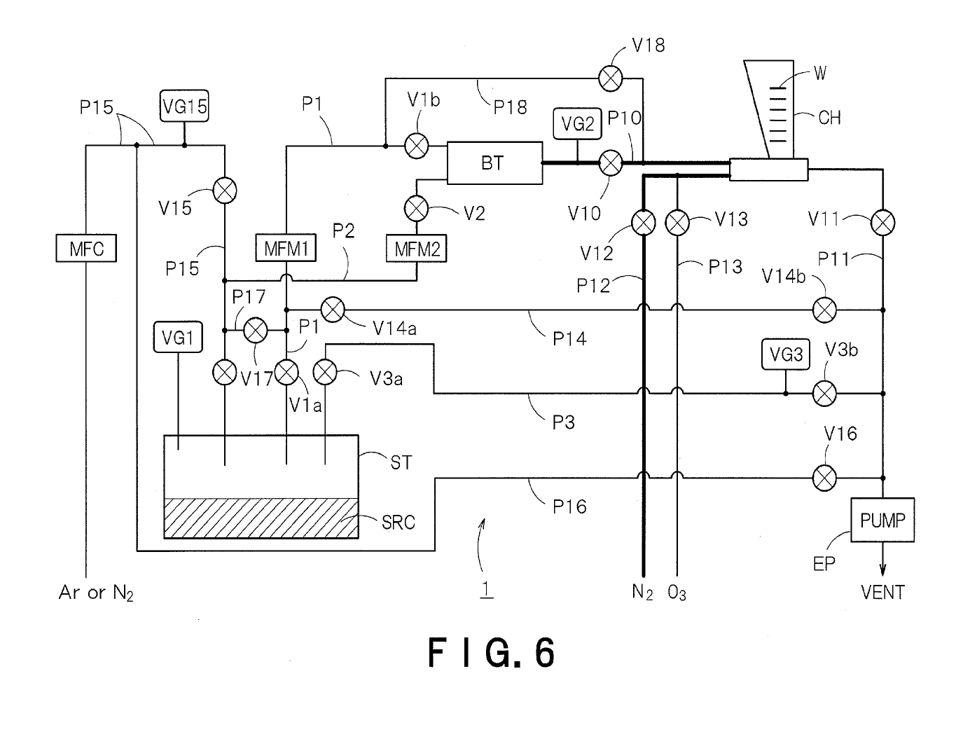

Subsequently, after the valves V2 and V15 are closed, the valve V10 opens the supply route of the source gas and supplies the source gas (a mixture gas of AlCl₃ and Ar, for example) from the buffer tank BT into the reaction chamber CH via the pipe P10 (Step S50) as shown in FIG. 6. Accordingly, the source gas stored or accumulated in the buffer tank BT is introduced into the reaction chamber CH and the source gas adheres on the surfaces of the semiconductor substrates W in the reaction chamber CH. At this time, the valves V1b and V2 close both the supply routes of the source gas and the inert gas and suppress the source gas in the source tank ST from being supplied any more to the reaction chamber CH. The valve V12 is somewhat closed and the reaction chamber CH is continuously purged with a small amount of the purge gas (N₂, for example). This is to prevent the source gas from entering (flowing back) from the reaction chamber CH to the pipe P12.

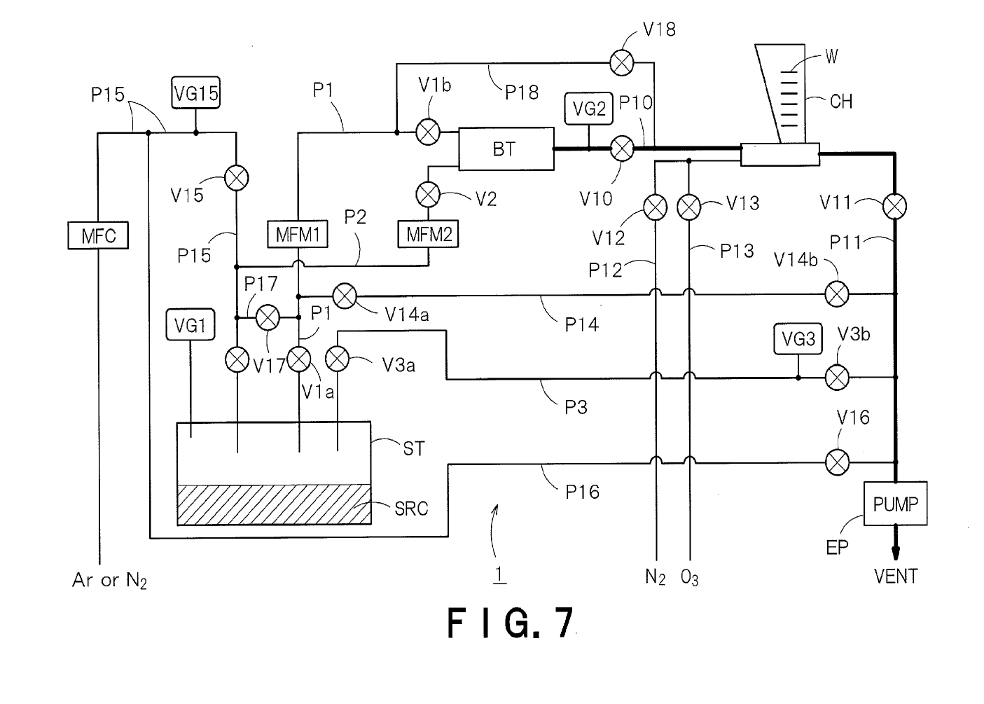

Next, after the valve V12 is closed, the valve V11 opens the gas discharging route to discharge the source gas remaining in the reaction chamber CH while the valve V10 is kept opened (Step S60) as shown in FIG. 7. Accordingly, the source gas having not adhered on the semiconductor substrates W and remaining in the reaction chamber CH is discharged by the discharging pump EP to outside of the reaction chamber CH. Because the valve V10 is also open at this time, the source gas stored or accumulated in the buffer tank BT is also discharged together with the source gas in the reaction chamber CH.

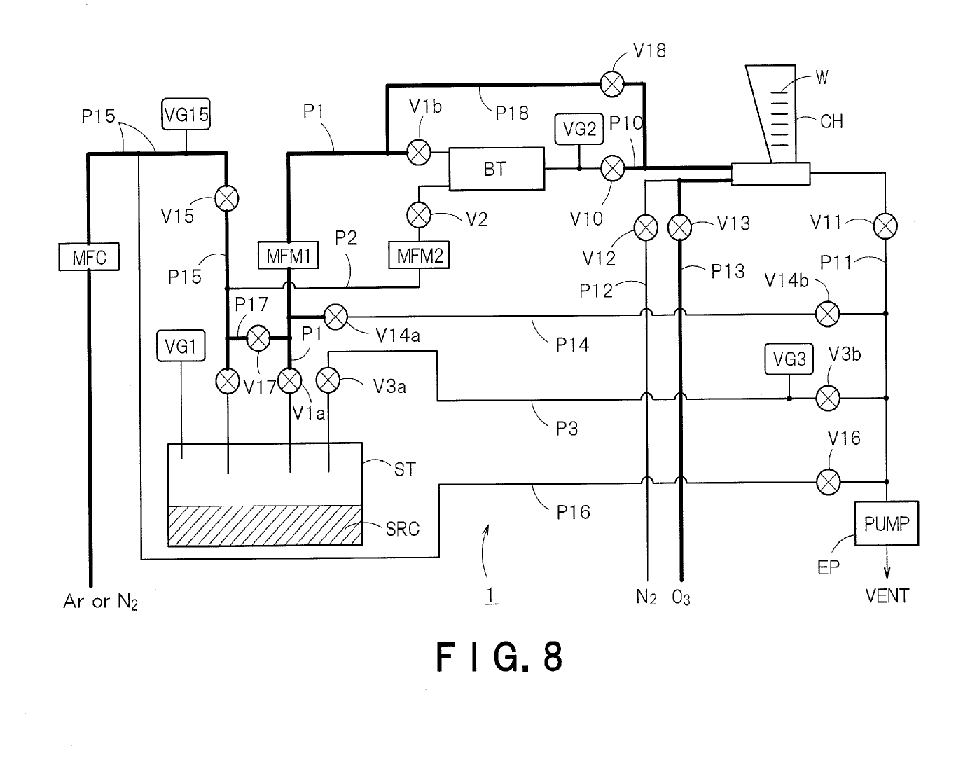

Subsequently, after the valves V10 and V11 are closed, the valve V13 opens the supply route of the oxidation gas and supplies the oxidation gas (O₃, for example) into the reaction chamber CH (Step S70) via the pipe P13 as shown in FIG. 8. At this time, the reaction chamber CH heats the semiconductor substrates W and oxidizes the source gas having adhered on the surfaces of the semiconductor substrates W. In this way, an oxide film at an atomic layer level can be formed on the surfaces of the semiconductor substrates W.

At this time, the valves V18, V17, and V15 are somewhat open and a small amount of the inert gas (Ar or N₂, for example) is supplied to the reaction chamber CH. This is to prevent the oxidation gas from entering (flowing back) from the reaction chamber CH to the pipe P10.

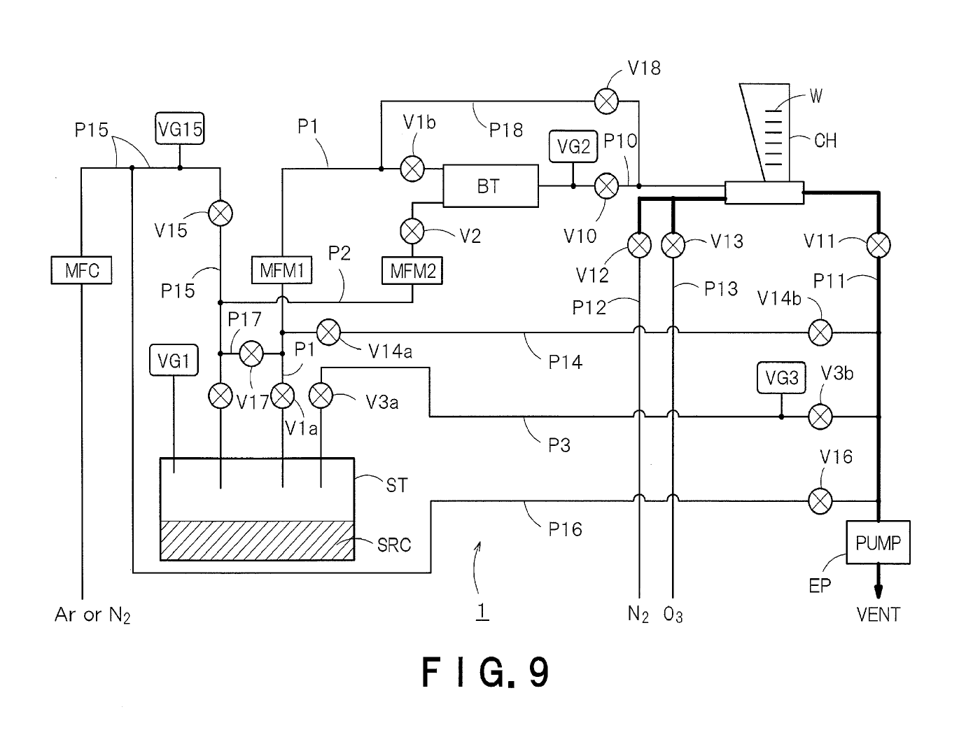

Next, after the valves V13, V18, V17, and V15 are closed, the valve V11 opens the gas discharging route and discharges the oxidation gas remaining in the reaction chamber CH via the pipe P11 (Step S80) as shown in FIG. 9. Accordingly, the oxidation gas not used to oxidize the source gas having adhered on the semiconductor substrates W is discharged to outside of the reaction chamber CH by the discharging pump EP.

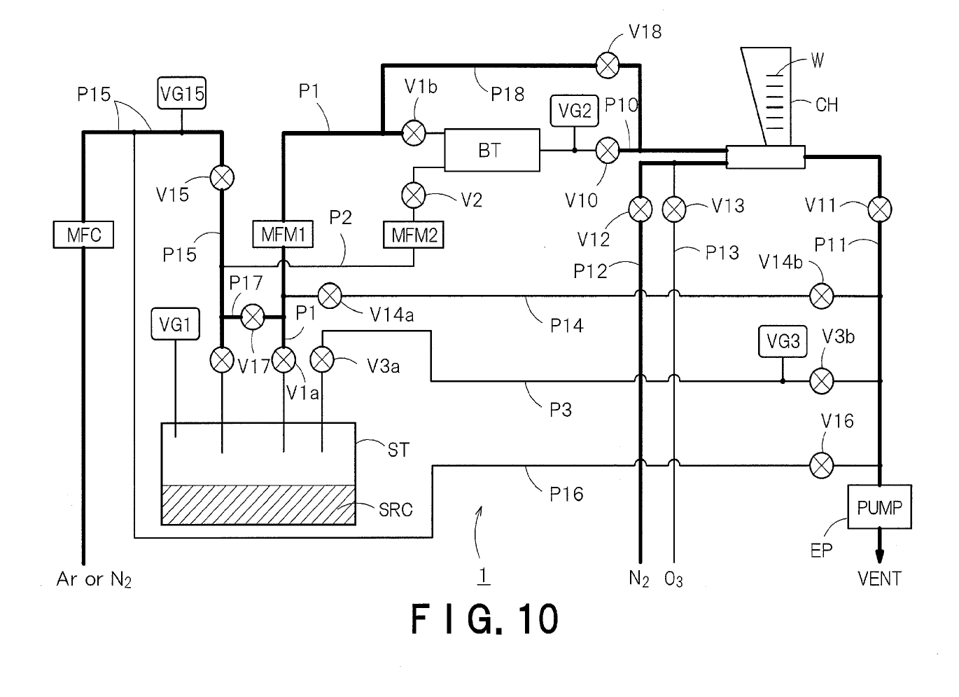

Subsequently, the valve V12 opens the supply route of the purge gas and supplies the purge gas (N₂, for example) into the reaction chamber CH via the pipe P12 (Step S90) as shown in FIG. 10. Accordingly, the oxidation gas in the reaction chamber CH is discharged and the reaction chamber CH is purged.

At this time, the valves V18, V17, and V15 are somewhat open and a small amount of the inert gas (Ar or N₂, for example) is supplied into the reaction chamber CH. This is to prevent the purge gas or the oxidation gas from entering (flowing back) from the reaction chamber CH to the pipe P10.

The first cycle is performed in this way. An oxide film (Al₂O₃, HfO₂, or Zr₂O₃, for example) at an atomic layer level is thereby formed on the surfaces of the semiconductor substrates W. After the first cycle is performed, Steps S20 to S90 shown in FIGS. 3 to 10 are repeated (NO at Step S100). Accordingly, an oxide film having a desired thickness is formed on the surfaces of the semiconductor substrates W. When an oxide film having a desired thickness is formed on the surfaces of the semiconductor substrates W (YES at Step S100), the film forming process ends. Particles such as the source and the reaction product are the most likely to be generated in the first cycle of the film forming process and are not generated so much in the following cycles. Therefore, Step S10 is performed in the first cycle of the film forming process and is not performed in the following cycles.

The film forming apparatus 1 according to the first embodiment includes the buffer tank BT between the reaction chamber CH and the source tank ST. The buffer tank BT can store or accumulate therein a certain amount of the source gas and supplies the certain amount of the source gas to the reaction chamber CH. Accordingly, the film forming apparatus 1 can supply a fixed amount of the source gas to the reaction chamber CH in each film forming cycle independent of the flow rate of the carrier gas.

Furthermore, in the first embodiment, the pipe P1 for supplying the source gas and the pipe P2 for supplying the inert gas are connected individually to the buffer tank BT. Therefore, the buffer tank BT can be pressurized to a fixed pressure with the inert gas after storing or accumulating therein the fixed amount of the source gas. That is, the source gas and the inert gas can be supplied separately to the buffer tank BT. Unlike a conventional function as the carrier, the inert gas in the first embodiment is used to pressurize the inside of the buffer tank BT and to send the source gas in the buffer tank BT sufficiently to the reaction chamber CH.

The film forming apparatus 1 according to the first embodiment has the pipe P3 that connects the source tank ST and the discharging pump EP separately from the pipes P1 and P2, and can vent the source gas directly from the source tank ST. Accordingly, particles such as the solid source and the reaction product in the first cycle are discharged via the pipe P3 and are suppressed from entering the reaction chamber CH and the buffer tank BT.

### Second Embodiment

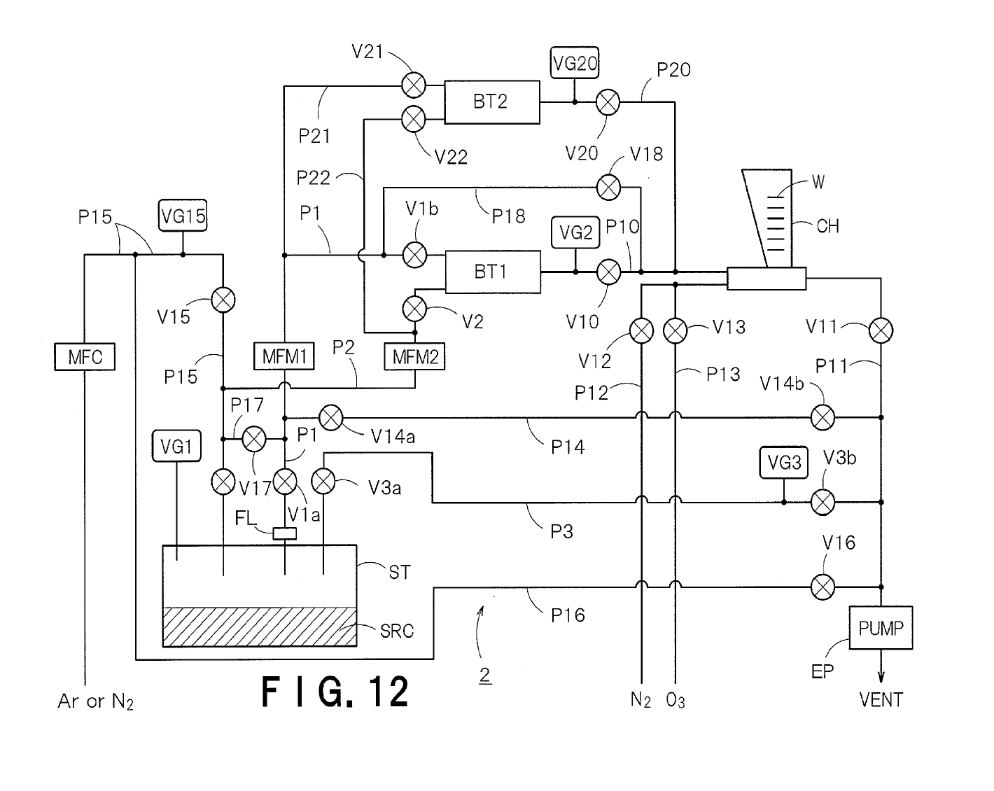

FIG. 12 shows a configuration of a film forming apparatus 2 according to a second embodiment. The film forming apparatus 2 includes two buffer tanks BT1 and BT2 connected in parallel between the reaction chamber CH and the source tank ST. The buffer tanks BT1 and BT2 can have the same configuration as that of the buffer tank BT in the first embodiment. The capacity of the buffer tank BT2 is substantially equal to that of the buffer tank BT1.

The buffer tank BT2 serving as a third container is connected to the reaction chamber CH via a pipe P20, is connected to the source tank ST via a pipe P21, and receives supply of the inert gas via a pipe P22. Therefore, the pipe P20 connects the buffer tank BT2 and the reaction chamber CH. The pipe P21 serving as a fourth pipe connects the source tank ST and the buffer tank BT2. The pipe P22 serving as a fifth pipe supplies the inert gas to the buffer tank BT2.

The pipe P21 and the pipe P22 are individually provided similarly to the pipe P1 and the pipe P2 and can send the source gas and the inert gas separately to the buffer tank BT2, respectively.

A valve V20 is provided on the pipe P20 and opens or closes a gas supply route from the buffer tank BT2 to the reaction chamber CH. A valve V21 serving as a fourth valve is provided on the pipe P21 and opens or closes a supply route of the source gas from the source tank ST to the buffer tank BT2. A valve V22 serving as a fifth valve is provided on the pipe P22 and opens or closes a supply route of the inert gas.

The buffer tanks BT1 and BT2 can simultaneously supply the source gas to the reaction chamber CH or alternately supply the source gas (or the mixture gas) to the reaction chamber CH.

When the buffer tanks BT1 and BT2 simultaneously supply the source gas to the reaction chamber CH, the source gas (or the mixture gas) corresponding to the total capacity of the buffer tanks BT1 and BT2 is supplied to the reaction chamber CH. In this case, the operations of the valves V20 to V22 and the timings thereof can be the same as the operations of the valves V10, V1b, and V2 and the timings thereof in the first embodiment, respectively. Therefore, explanations of operations of the valves V20 to V22 are omitted.

When the buffer tanks BT1 and BT2 alternately supply the source gas (or the mixture gas) to the reaction chamber CH, the buffer tank BT2 stores or accumulates therein the source gas from the source tank ST and the inside of the buffer tank BT2 is pressurized with the inert gas during a period when the buffer tank BT1 supplies the source gas (or the mixture gas) to the reaction chamber CH and the reaction chamber CH forms a deposited film with the source gas. On the other hand, during a period when the buffer tank BT2 supplies the source gas (or the mixture gas) to the reaction chamber CH and the reaction chamber CH forms a deposited film with the source gas, the buffer tank BT1 stores or accumulates therein the source gas as from the source tank ST and the inside of the buffer tank BT1 is pressurized with the inert gas.

For example, while the buffer tank BT1 supplies the source gas to the reaction chamber CH and the reaction chamber CH forms a deposited film with the source gas, the valve V21 opens the supply route of the source gas of the pipe P21 and then the valve V22 opens the supply route of the inert gas of the pipe P22 in order to store or accumulate the source gas and the inert gas in the buffer tank BT2. That is, in the film forming apparatus 2, while Steps S50 to S90 in FIG. 11 are performed in the buffer tank BT1, Steps S30 and S40 are performed in the buffer tank BT2. At this time, the valve V20 keeps the gas supply route from the buffer tank BT2 to the reaction chamber CH closed.

On the other hand, while the buffer tank BT2 supplies the source gas to the reaction chamber CH and the reaction chamber CH forms a deposited film with the source gas, the valve V1b opens the supply route of the source gas of the pipe P1 and then the valve V2 opens the supply route of the inert gas of the pipe P2 in order to store or accumulate the source gas and the inert gas in the buffer tank BT1. That is, in the film forming apparatus 2, while Steps S50 to S90 in FIG. 11 are performed in the buffer tank BT2, Steps S30 and S40 are performed in the buffer tank BT1. At this time, the valve V10 keeps the gas supply route from the buffer tank BT1 to the reaction chamber CH closed.

As described above, the film forming apparatus 2 according to the second embodiment forms an oxide film on the semiconductor substrates W simultaneously or alternately using the two buffer tanks BT1 and BT2. Because a larger amount of the source gas can be supplied to the reaction chamber CH through simultaneous supply of the source gas by the buffer tanks BT1 and BT2 to the reaction chamber CH, the film forming apparatus 2 can process more semiconductor substrates W. Furthermore, alternate supply of the source gas by the buffer tanks BT1 and BT2 to the reaction chamber CH enables the film forming apparatus 2 to achieve the film forming cycle smoothly and to perform the film forming process more quickly and more efficiently. Furthermore, the second embodiment can also achieve effects of the first embodiment.

### MODIFICATION

In the first and second embodiments, the film forming apparatus 1 or 2 can further include a filter provided in the pipe P1 or P21 as shown in FIG. 1. The filter is formed in a shape of meshes and allows the source gas to pass through while not allowing particles larger than the meshes to pass through. Accordingly, it is possible to further suppress particles such as the solid source and the reaction product from entering the buffer tank BT1 and the reaction chamber CH.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus comprising:
a reaction chamber being capable of housing a semiconductor substrate and being capable of forming a deposited film on a surface of the semiconductor substrate;
a first container storing a source of the deposited film;
a second container storing a source gas generated in the first container and supplying the source gas to the reaction chamber;
a first pipe connecting the first container and the second container; and
a second pipe supplying an inert gas to the second container.

2. The apparatus of claim 1, wherein a capacity of the second container is smaller than that of the first container.

3. The apparatus of claim 1, further comprising a third pipe connecting the first container and a discharging device.

4. The apparatus of claim 2, further comprising a third pipe connecting the first container and a discharging device.

5. The apparatus of claim 3, wherein the first to third pipes are individually provided.

6. The apparatus of claim 4, wherein the first to third pipes are individually provided.

7. The apparatus of claim 1, further comprising:
a first valve on the first pipe, the valve opening or closing a supply route of the source gas; and
a second valve on the second pipe, the valve opening or closing a supply route of the inert gas, wherein
the first valve opens the supply route of the source gas of the first pipe with a supply route of the inert gas from the second container to the reaction chamber being kept closed when the source gas in the first container is to be stored in the second container, and
the first valve closes the supply route of the source gas of the first pipe and the second valve closes the supply route of the inert gas of the second pipe when the source gas is to be supplied from the second container to the reaction chamber.

8. The apparatus of claim 7, wherein the second valve opens the supply route of the inert gas in order to pressurize the source gas stored in the second container before the source gas is supplied from the second container to the reaction chamber.

9. The apparatus of claim 3, further comprising a third valve opening or closing a gas discharging route of the third pipe, wherein
the third valve opens the gas discharging route of the third pipe before the source gas is stored from the first container to the second container.

10. The apparatus of claim 1, further comprising:
a third container storing a source gas generated in the first container and supplying the source gas to the reaction chamber;
a fourth pipe connecting the first container and the third container; and
a fifth pipe supplying an inert gas to the third container.

11. The apparatus of claim 10, wherein a capacity of the third container is substantially equal to that of the second container.

12. The apparatus of claim 10, wherein the fourth pipe and the fifth pipe are individually provided.

13. The apparatus of claim 11, wherein the fourth pipe and the fifth pipe are individually provided.

14. The apparatus of claim 10, further comprising:
a fourth valve on the fourth pipe, the valve opening or closing a supply route of the source gas; and
a fifth valve on the fifth pipe, the valve opening or closing a supply route of the inert gas, wherein
the fourth valve opens the supply route of the source gas of the fourth pipe with a gas supply route from the third container to the reaction chamber being kept closed when the source gas in the first container is to be stored in the third container, and
the fourth valve closes the supply route of the source gas of the fourth pipe and the fifth valve closes the supply route of the inert gas of the fifth pipe when the source gas is to be supplied from the third container to the reaction chamber.

15. The apparatus of claim 14, wherein the fifth valve opens the supply route of the inert gas in order to pressurize the source gas stored in the third container before the source gas is supplied from the third container to the reaction chamber.

16. The apparatus of claim 10, wherein
the third container stores the source gas while the source gas is supplied from the second container to the reaction chamber and the deposited film is formed in the reaction chamber with the source gas, and
the second container stores the source gas while the source gas is supplied from the third container to the reaction chamber and the deposited film is formed in the reaction chamber with the source gas.

17. The apparatus of claim 11, wherein
the third container stores the source gas while the source gas is supplied from the second container to the reaction chamber and the deposited film is formed in the reaction chamber with the source gas, and
the second container stores the source gas while the source gas is supplied from the third container to the reaction chamber and the deposited film is formed in the reaction chamber with the source gas.

18. The apparatus of claim 12, wherein
the third container stores the source gas while the source gas is supplied from the second container to the reaction chamber and the deposited film is formed in the reaction chamber with the source gas, and
the second container stores the source gas while the source gas is supplied from the third container to the reaction chamber and the deposited film is formed in the reaction chamber with the source gas.

19. The apparatus of claim 1, further comprising a filter in the first pipe.

20. The apparatus of claim 10, further comprising a filter in the fourth pipe.
